(19) United States
(12) Patent Application Publication
(10) Pub. No.: US 2024/0014734 A1
(43) Pub. Date: Jan. 11, 2024

(54) VOLTAGE CONVERSION DEVICE AND MANUFACTURING METHOD

(71) Applicant: YAZAKI CORPORATION, Tokyo (JP)

(72) Inventor: Tsunehiro Watanabe, Makinohara-shi (JP)

(21) Appl. No.: 18/474,120

(22) Filed: Sep. 25, 2023

Related U.S. Application Data
(63) Continuation of application No. PCT/JP2022/038109, filed on Oct. 12, 2022.

(30) Foreign Application Priority Data
Nov. 17, 2021 (JP) 2021-187351

(51) Int. Cl. H02M 3/00; H05K 1/18

(52) U.S. Cl. CPC H02M 3/003; H05K 1/181; H05K 2201/10015

(57) ABSTRACT

A voltage conversion device includes: a board on which an electronic component having a power conversion function is mounted; and a capacitor unit detachably attached to the board and electrically connected to the board. The capacitor unit includes: a capacitor; a capacitor board on which the capacitor is mounted; and resin by which the capacitor and the capacitor board are enclosed

### CROSS-REFERENCE TO RELATED APPLICATIONS

This is a continuation of International Application No. PCT/JP2022/038109 filed on Oct. 12, 2022, and claims priority from Japanese Patent Application No. 2021-187351 filed on Nov. 17, 2021, the entire content of which is incorporated herein by reference.

### TECHNICAL FIELD

The present invention relates to a voltage conversion device and a manufacturing method.

### BACKGROUND ART

In the related arts, there is a voltage conversion device that converts a DC input voltage into a predetermined voltage. For example, one of the voltage conversion devices of the related arts is mounted on a vehicle such as an electric vehicle (EV), and uses an electronic component (such as a transformer) having a power conversion function to step up (or step down) the voltage to a predetermined voltage according to the control of the vehicle and charge a storage battery or the like (for example, refer to Patent Literature 1).

### CITATION LIST

### Patent Literature

Patent Literature 1: JP2011-30355A

### SUMMARY OF INVENTION

### Technical Problem

In general, in a voltage conversion device, noise is generated in the current due to the influence of switching and the like during transformation, and thus it is necessary to remove the noise generated in the current. Many voltage conversion devices in the related arts cope with the above noise by mounting a capacitor having a noise filter function on a board including a transformer or the like.

Incidentally, the voltage conversion device described above may be accelerated due to the influence of the vehicle in which the voltage conversion device is mounted. Here, the capacitor mounted on the board is greatly affected by acceleration due to the shape of the capacitor itself, and there is a concern that the capacitor is detached from the board. To cope with the detachment of the capacitor from the board as described above, there is a method of holding down a lower end portion of the capacitor using synthetic resin such as plastic as a base. However, in the above method, the base is expensive, and thus there is a concern that the manufacturing cost will increase.

In voltage conversion devices of the related arts, the board including the capacitor is often housed inside a housing, and thus replacement of the capacitor with respect to the board is not taken into consideration. On the other hand, in consideration of the failure of the capacitor due to the influence of heat or the deterioration of the capacitor over time due to power reception at a high temperature, more capacitors than necessary were mounted on the board. As a result, the number of capacitors in the voltage conversion device increases, further increasing the manufacturing cost.

The voltage conversion device and the manufacturing method according to the embodiments can reduce the manufacturing cost.

### Solution to Problem

According to an embodiment, there is provided a voltage conversion device including:
a board on which an electronic component having a power conversion function is mounted; and
a capacitor unit detachably attached to the board and electrically connected to the board, in which
the capacitor unit includes
a capacitor,
a capacitor board on which the capacitor is mounted, and
resin by which the capacitor and the capacitor board are enclosed.

According to another embodiment, there is provided a method for manufacturing the voltage conversion device, the method including:
a selection step of selecting one or a plurality of the capacitor units from among a plurality of capacitor units including different types of capacitors; and
a mounting step of mounting the capacitor unit selected in the selection step on the board.

### Advantageous Effects of Invention

According to the voltage conversion device according to one embodiment, the capacitor unit is detachably attached to the board on which the electronic component having the power conversion function is mounted. As a result, even when a failure in the capacitor due to the influence of heat or deterioration of the capacitor over time due to power reception at a high temperature occurs, the capacitor unit can be removed from the board and replaced. In other words, since the capacitor unit can be replaced with respect to the board, there is no need to mount more capacitors than necessary on the capacitor board. As a result, the voltage conversion device having such configuration includes a smaller number of capacitors compared to the voltage conversion device of the related arts.

According to the voltage conversion device configured as described above, even when the voltage conversion device is accelerated, for example, the capacitor and the capacitor board are enclosed by the resin, and thus the capacitor is prevented from being detached from the capacitor board. Accordingly, there is no need to provide an expensive base unlike the voltage conversion device of the related arts.

As described above, the manufacturing cost of the voltage conversion device configured as described above is reduced compared to the voltage conversion device of the related arts.

Note that the capacitor unit in the voltage conversion device configured as described above is assumed as a noise filter having a function of removing noise generated during voltage conversion, but is not limited thereto. The manufacturing method according to the embodiment can obtain the above-described effects of the voltage conversion device.

### BRIEF DESCRIPTION OF DRAWINGS

FIG. 1 is a schematic cross-sectional view showing a voltage conversion device according to an embodiment of the present invention.

FIG. 2 is a schematic cross-sectional view of a capacitor unit shown in FIG. 1.

FIG. 3 is a schematic cross-sectional view of the capacitor unit shown in FIG. 2 as viewed from above.

FIG. 4 is an enlarged schematic cross-sectional view for explaining a mounting step of the capacitor unit on a board.

FIG. 5 is a view corresponding to FIG. 3 according to another embodiment.

### DESCRIPTION OF EMBODIMENTS

### Embodiment

A voltage conversion device 1 according to an embodiment of the present invention will be described below with reference to the drawings. The voltage conversion device 1 is mounted in a vehicle, that is, an automobile such as an electric vehicle or a connected car having a function as an information and communication technology (ICT) terminal.

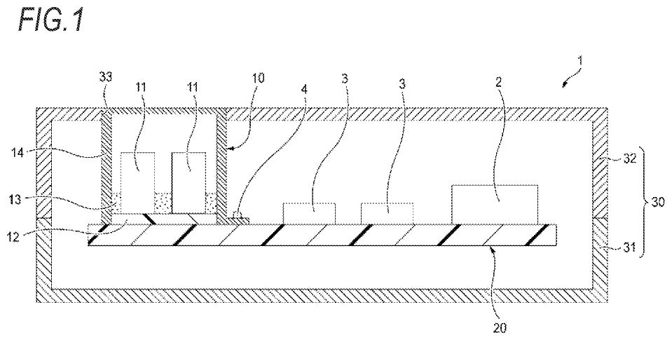

As shown in FIG. 1, the voltage conversion device 1 includes a capacitor unit 10, a board 20 to which the capacitor unit 10 is detachably attached, and a case 30 that houses the capacitor unit 10 and the board 20. Hereinafter, the capacitor unit 10, the board 20, and the case that configure the voltage conversion device 1 will be described in order.

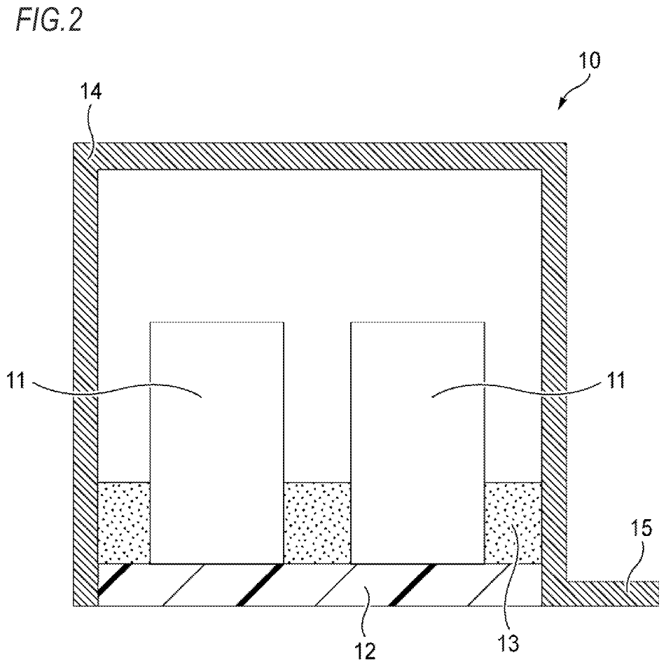

First, the capacitor unit 10 will be described. As shown in FIGS. 1 and 2, the capacitor unit 10 includes a capacitor 11, a capacitor board 12 on which the capacitor 11 is mounted, resin 13 enclosing the capacitor 11 and the capacitor board 12, and a cover 14 attached to the resin 13 enclosing the capacitor 11 and the capacitor board 12.

Since the capacitor 11 is used as a noise filter that removes noise generated during voltage conversion by the voltage conversion device 1, the capacitor 11 preferably has a large capacitance (that is, a low impedance). Therefore, as the capacitor 11, for example, an aluminum electrolytic capacitor or the like is used.

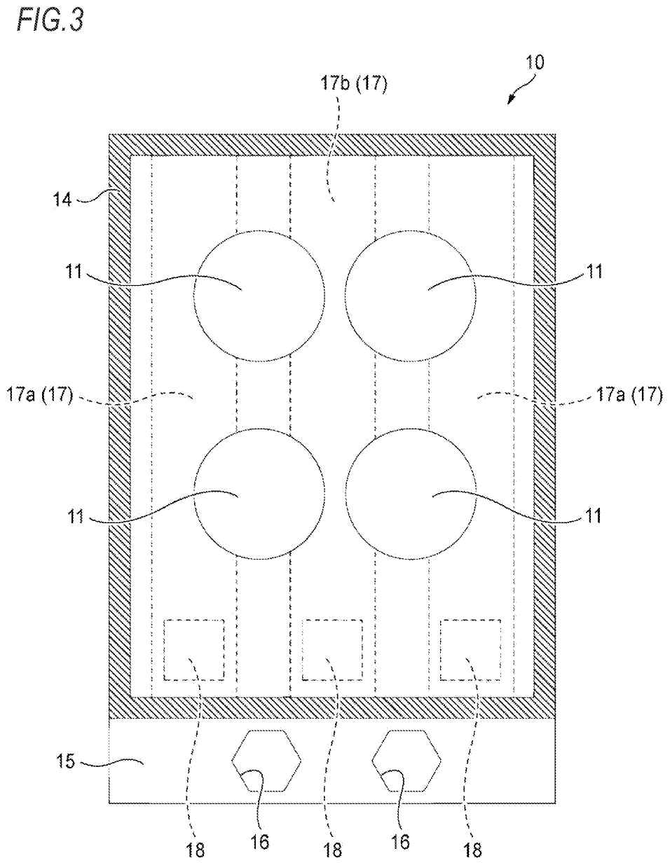

As shown in FIG. 3, the capacitor board 12 is provided with a potential area 17 electrically connected to a terminal portion 18, which will be described later. The potential area 17 is, for example, a circuit pattern provided on the capacitor board 12. The potential area 17 includes an anode area 17a connected to an electrode of a battery or the like and a ground area 17b connected to the ground. The capacitor board 12 is provided with the terminal portion 18 that is elastically and electrically connected to a spring terminal 21 of the board 20, which will be described later.

The resin 13 is composed of solidified resin capable of enclosing the capacitor 11 and the capacitor board 12. However, the resin 13 is not limited thereto as long as the capacitor 11 and the capacitor board 12 are enclosed.

The cover 14 is made of metal material. As shown in FIGS. 2 and 3, the cover 14 has a substantially rectangular cylindrical shape having a bottom, of which a lower surface is open. A flange 15 extending toward an outside of the cover 14 is provided at a lower end portion of a side wall of the cover 14.

The flange 15 is provided with screw holes 16 through which screws 4 are inserted when the capacitor unit 10 is mounted on the board 20. In other words, the flange 15 functions as a fastening portion when the capacitor unit 10 is mounted on the board 20.

Here, a method for manufacturing the capacitor unit 10 will be described. First, a plurality of capacitors 11 are mounted on the board 20. Specifically, a pair of lead wires (not shown) of each capacitor 11 are electrically connected to the anode area 17a and the ground area 17b of the board 20, respectively.

Next, the capacitor 11 and the capacitor board 12 are enclosed by the resin 13. Specifically, the capacitor board 12 on which the capacitors 11 are mounted is housed in, for example, a container (not shown), the resin 13 is poured into the container, and the resin 13 is solidified by various methods. Here, the resin 13 is poured until the lower end portion of the capacitor 11 is buried. As a result, the capacitor 11 and the capacitor board 12 are enclosed by the resin 13.

Next, the cover 14 is attached to the resin 13 in which the capacitor 11 and the capacitor board 12 are enclosed. Specifically, the resin 13 in which the capacitor 11 and the capacitor board 12 are enclosed is covered with the cover 14 from above. Thus, the capacitor unit 10 is obtained.

In the present embodiment, the cover 14 has a shape corresponding to the capacitor board 12 including the capacitor 11 and the resin 13, and thus the capacitor board 12 is fitted in the opening part of the lower surface of the cover 14.

However, the manner in which the cover 14 is attached to the resin 13 in which the capacitor 11 and the capacitor board 12 are enclosed is not limited thereto. The method for manufacturing the capacitor unit 10 is not limited to the above, and may be set as appropriate. The capacitor unit 10 has been described above.

Next, the board 20 will be described. The board 20 configures an electronic (electrical) circuit of the voltage conversion device 1. The board 20 is configured by, for example, a printed circuit board (PCB) or the like.

In other words, the board 20 is formed by printing a wiring pattern (print pattern) with a conductive material such as copper on an insulating layer made of an insulating material such as epoxy resin, glass epoxy resin, paper epoxy resin, or ceramic, thereby forming a circuit body with the wiring pattern.

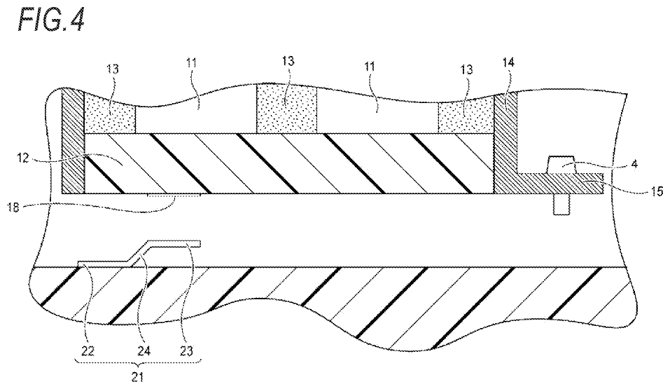

As shown in FIG. 4, the board 20 includes the spring terminal 21 having a cantilever shape. The spring terminal 21 includes a board connection portion 22 electrically connected to the circuit pattern of the board 20, a terminal connection portion 23 electrically connected to the terminal portion 18 of the capacitor unit 10, and an intermediate portion 24 positioned between the board connection portion 22 and the terminal connection portion 23, which are integrated with each other.

As shown in FIG. 1, the board 20 is mounted with a transformer 2, a heat sink 3, and the like in addition to the capacitor unit 10. The transformer 2 steps up or steps down an AC voltage converted from a DC power supply, for example, by controlling on/off of a switch in a switching element (not shown). The heat sink 3 has a function of dissipating and exhausting heat generated during transformation.

Various electronic components are mounted on the board 20 in addition to the transformer 2 and the heat sink 3, but the description thereof will be omitted. Note that the transformer 2 corresponds to “an electronic component having a power conversion function”. The board 20 has been described above.

Next, the case 30 will be described. The case 30 is made of a metal material and houses the capacitor unit 10 and the board 20. As shown in FIG. 1, the case 30 includes a case main body 31 of which an upper surface is open and a case cover 32 assembled to the case main body 31 to cover the upper surface opening of the case main body 31. For example, the case main body 31 and the case cover 32 are prevented from being separated from the assembled state by locking the locking portions provided on both sides.

An opening 33 corresponding to the shape of an upper surface of the cover 14 of the capacitor unit 10 is provided at a part of an upper surface of the case cover 32. When the case 30 houses the capacitor unit 10 and the board 20, the opening 33 is closed by the upper surface of the cover 14. The case 30 has been described above.

Above, the capacitor unit 10, the board 20, and the case 30 that configure the voltage conversion device 1 have been described. The voltage conversion device 1 is obtained by mounting the capacitor unit 10 on the board 20 and housing the board 20 with the capacitor unit 10 mounted thereon in the case 30. A method for manufacturing the voltage conversion device 1 will be described below.

First, one or a plurality of capacitor units 10 are selected from among a plurality of capacitor units 10 including different types of capacitors 11 (the step corresponds to a “selection step”).

In general, environments such as temperature differ depending on countries and regions, and thus the number of mounted capacitors 11 and the like differ depending on countries and regions where vehicles in which the voltage conversion device 1 is mounted are used. Therefore, the capacitor unit 10 in which the capacitor 11 corresponding to the country or region is mounted is selected. A type of the capacitor 11 of the present embodiment includes a capacitance of the capacitor 11, the number of mounted capacitors 11, and the like, and the type of the capacitor 11 is a generic term therefor.

Next, the capacitor unit 10 selected by the selection step is mounted on the board 20 (the step corresponds to a “mounting step”). Specifically, the capacitor unit 10 is placed at a predetermined position on the board 20, and the screws 4 are inserted through the screw holes 16 of the flange 15 of the capacitor unit 10 and the screw holes (not shown) of the board 20 for fastening.

The predetermined position is preferably a position away from the transformer 2, and more preferably a position sandwiching the heat sink 3 between the capacitor unit 10 and the transformer 2. This is because, in a high-temperature environment, a failure in the operation or the like of the capacitor 11, or deterioration over time due to power reception at a high temperature may occur. Note that the mounting (attachment) of the capacitor unit 10 to the board 20 is not limited thereto.

As shown in FIG. 4, when the capacitor unit 10 is mounted on the board 20, the terminal portions 18 are moved downward while being arranged above the spring terminals 21 of the board 20. Thereby, the terminal portion 18 and the spring terminal 21 are elastically and electrically connected. That is, the capacitor unit 10 and the board 20 are electrically connected.

Next, the board 20 on which the capacitor unit 10 is mounted is housed in the case 30 (housing step). Specifically, the board 20 on which the capacitor unit 10 is mounted is placed on the case main body 31, and the case cover 32 is assembled to the case main body 31. Here, the upper surface of the cover 14 of the capacitor unit 10 is fitted into the opening 33 of the case cover 32. Thereby, the capacitor unit 10 and the board 20 are housed in the case 30.

From the viewpoint of waterproofness, it is preferable to provide a waterproof member such as packing between the cover 14 of the capacitor unit 10 and the opening 33 of the case 30. Thus, the voltage conversion device 1 is obtained by the above steps.

For example, when replacing the capacitor unit 10, the board 20 on which the capacitor unit 10 is mounted may be taken out from the case 30, the capacitor unit 10 may be removed from the board 20, a new capacitor unit 10 may be selected, and the above-described steps may be performed. A method for manufacturing the voltage conversion device 1 has been described above.

According to the voltage conversion device 1 according to the present embodiment, the capacitor unit 10 is detachably attached to the board 20. Accordingly, since the capacitor unit 10 can be replaced with respect to the board 20, there is no need to mount more capacitors 11 than necessary on the capacitor board 12. Heat transfer to the capacitor 11 can be reduced by forming the capacitor 11 as the capacitor unit 10 and separately from the board 20 and the case 30. As a result, the voltage conversion device 1 according to the present embodiment can reduce the number of mounted capacitors 11 compared to the voltage conversion device of the related arts.

According to the voltage conversion device 1 according to the present embodiment, even when the voltage conversion device 1 is accelerated, for example, the capacitor 11 and the capacitor board 12 are enclosed by the resin 13, and thus the capacitor 11 is prevented from being detached from the capacitor board 12 (that is, vibration resistance is improved). Accordingly, there is no need to provide an expensive base unlike the voltage conversion device of the related arts.

As described above, the manufacturing cost of the voltage conversion device 1 according to the present embodiment is reduced compared to the voltage conversion device of the related arts.

According to the voltage conversion device 1 of the present embodiment, the upper surface of the cover 14 of the capacitor unit 10 is configured to close the opening 33 provided in the case cover 32 of the case 30. As a result, the height of the case cover 32 can be matched with the height of the capacitor unit 10 mounted on the board 20, and an increase in the size of the voltage conversion device 1 can be prevented.

According to the voltage conversion device 1 according to the present embodiment, the terminal portion 18 of the capacitor unit 10 and the spring terminal 21 of the board 20 are elastically connected. Thereby, the capacitor unit 10 and the board 20 can be easily electrically connected.

The manufacturing method according to the present embodiment can also achieve the above-described “functions and effects” of the voltage conversion device 1.

### Other Aspects

The present invention is not limited to the above-described embodiments, but appropriate modifications, improvements, and the like are possible. Any material, shape, dimensions, number, location, and the like of each configuration element in the above-described embodiments can be adopted as long as the present invention can be achieved, and are not limited.

Although only one flange 15 is provided on the cover 14 of the capacitor unit 10 in the above embodiment, a plurality of flanges 15 may be provided. By providing a plurality of flanges 15 on the cover 14, the capacitor unit 10 is more appropriately prevented from being detached from the board 20.

In the above embodiment, the capacitor 11 was connected to the ground via the terminal portion 18, but may be connected to the ground via the flange 15 and the screw 4, which are the fastening portions with the board 20, for example.

In the above embodiment, the capacitor unit 10 is mounted on the board 20 while the case cover 32 is removed from the case main body 31, but may be configured to be mounted on the board 20 while the case cover 32 is assembled to the case main body 31. That is, the capacitor unit 10 may be mounted by inserting the capacitor unit 10 from the opening 33 of the case cover 32 toward the board 20.

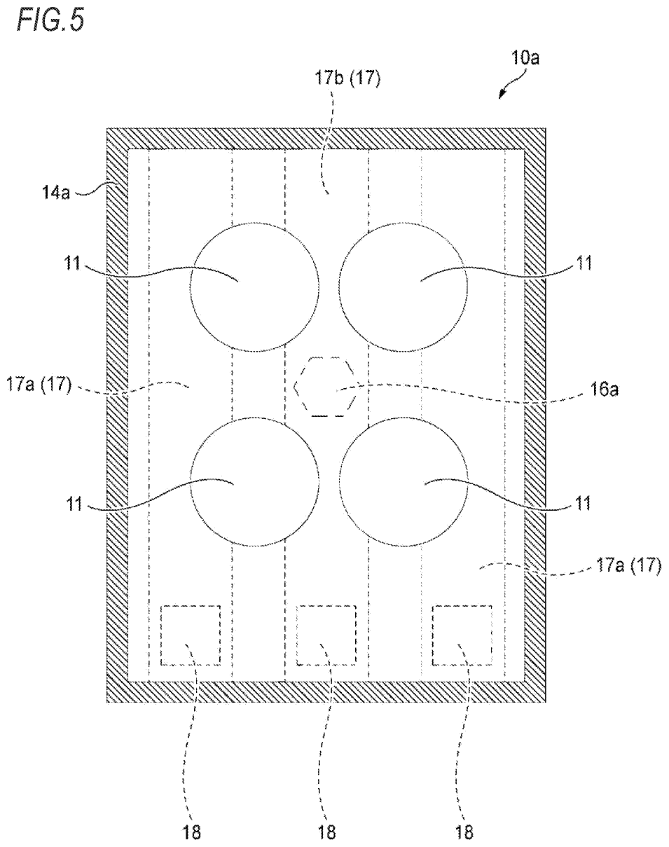

As shown in FIG. 5, the cover 14a of the capacitor unit 10a may not include the flange portion. Here, the screw hole 16a may be provided at the center part of the capacitor board 12, for example. As a result, the size of the capacitor unit 10a can be reduced.

Here, the features of the voltage conversion device and the manufacturing method according to the present embodiment described above are briefly listed in <1> to <4> below.

<1> A voltage conversion device (1) including:
a board (20) on which an electronic component having a power conversion function is mounted; and
a capacitor unit (10) detachably attached to the board and electrically connected to the board, in which
the capacitor unit (10) includes
a capacitor (11),
a capacitor board (12) on which the capacitor is mounted, and
resin (13) by which the capacitor and the capacitor board are enclosed.

<2> The voltage conversion device (1) according to <1> described above, further including:
a case (30) that houses the board (20) and the capacitor unit (10), in which
a part of the case (30) is provided with an opening (33), and
the capacitor unit (10) further includes a metal cover (14) that is attached to the resin (13) by which the capacitor (11) and the capacitor board (12) are enclosed and closes the opening (33).

<3> The voltage conversion device (1) according to <1> or <2> described above, in which a spring terminal (21) provided on the board (20) and a terminal portion (18) provided on the capacitor unit (10) are elastically connected.

<4> A method for manufacturing the voltage conversion device (1) according to any one of <1> to <3> described above, the method including:
a selection step of selecting one or a plurality of the capacitor units (10) from among a plurality of capacitor units (10) including different types of capacitors (11); and
a mounting step of mounting the capacitor unit (10) selected in the selection step on the board (20).

While the present invention has been described in detail and with reference to specific embodiments, it will be apparent to those skilled in the art that various changes or modifications can be made without departing from the spirit and scope of the present invention.

The present application is based on Japanese Patent Application (No. 2021-187351) filed on Nov. 17, 2021, and the content thereof is incorporated herein by reference.

### INDUSTRIAL APPLICABILITY

According to one embodiment, it is possible to provide a voltage conversion device and a manufacturing method capable of reducing manufacturing cost. The present invention having the effect is useful for voltage conversion devices and manufacturing methods.

### REFERENCE SIGNS LIST

1 Voltage conversion device
2 Transformer
3 Heat sink
4 Screw
10, 10a Capacitor unit
11 Capacitor
12 Capacitor board
13 Resin
14, 14a Cover
15 Flange
16, 16a Screw hole
17 Potential area
17a Anode area
17b Ground area
18 Terminal portion
20 Board
21 Spring terminal
22 Board connection portion
23 Terminal connection portion
24 Intermediate portion
30 Case
31 Case main body
32 Case cover
33 Opening

1. A voltage conversion device comprising:
a board on which an electronic component having a power conversion function is mounted; and
a capacitor unit detachably attached to the board and electrically connected to the board, wherein
the capacitor unit includes:
a capacitor;
a capacitor board on which the capacitor is mounted; and
resin by which the capacitor and the capacitor board are enclosed.

2. The voltage conversion device according to claim 1, further comprising:
a case that houses the board and the capacitor unit, wherein:
a part of the case is provided with an opening; and
the capacitor unit further includes a metal cover that is attached to the resin by which the capacitor and the capacitor board are enclosed and closes the opening.

3. The voltage conversion device according to claim 1, wherein
a spring terminal provided on the board and a terminal portion provided on the capacitor unit are elastically connected.

4. A method for manufacturing the voltage conversion device according to claim 1, the method comprising:
selecting one or a plurality of the capacitor units from among a plurality of capacitor units including different types of capacitors; and
mounting the capacitor unit selected in the selecting on the board.
